(19) United States
(12) Patent Application Publication
(10) Pub. No.: US 2003/0041798 A1
(43) Pub. Date: Mar. 6, 2003

(54) Coated silicon wafer and process for its production

(75) Inventors: Guido Wenski, Burghausen (DE); Ute Mareck, Garching (DE); Thomas Altmann, Haiming (DE)

Correspondence Address: WILLIAM COLLARD, COLLARD & ROE, P.C., 1077 NORTHERN BOULEVARD, ROSLYN, NY, 11576, US

(73) Assignee: WACKER SILTRONIC GESELLSCHAFT FUR HALBLEITERMATERIALEN AG, BURGHAUSEN (DE)

(21) Appl. No.: 10/233,721

(22) Filed: Sep. 3, 2002

(30) Foreign Application Priority Data
Sep. 6, 2001 (DE) 101 43 741.2

(51) Int. Cl. C30B 23/00; C30B 25/00; C30B 28/12; C30B 28/14

(52) U.S. Cl. 117/84

(57) ABSTRACT

A silicon wafer is provided having a polished front surface with an epitaxial coating and a polished back surface, which is distinguished by a SFQRₘₐₓ value of less than or equal to 0.10 μm (26 mm×8 mm; 99%). There is also a process for producing silicon wafers of this type by sawing up a single crystal, carrying out an abrasive step, simultaneously polishing a front surface and a back surface of at least three silicon wafers, and applying an epitaxial coating. This process includes the following conditions being satisfied simultaneously: (a) before the simultaneous polishing, the silicon wafers have a concave thickness distribution, the center thickness being 1 μm to 10 μm lower than the edge thickness, and this thickness difference differing by less than or equal to 3 μm within one polishing run; (b) the mean thickness of the silicon wafers prior to the simultaneous polishing differs by less than or equal to 3 μm within one polishing run; and (c) the thickness of the carriers used during the simultaneous polishing is 1 μm to 5 μm lower than the thickness of the finished polished silicon wafers.

### BACKGROUND OF THE INVENTION

1. Field of the Invention

The present invention relates to a silicon semiconductor wafer which has been epitaxially coated on the front surface and has an improved flatness, and to a process for producing a wafer of this type. Epitaxially coated silicon wafers with a very high flatness are suitable for use in the semiconductor industry, in particular for the fabrication of electronic components with line widths of less than or equal to 0.10 μm.

2. The Prior Art

A silicon wafer which is suitable in particular for the fabrication of electronic components with line widths of less than or equal to 0.10 μm, generally referred to as the 0.10 μm technology generation, must have a large number of particular properties. In this context, one critical property is its local flatness. The modern stepper technology requires optimum local flatnesses in all subregions of a surface of the wafer, expressed, for example, as SFQR (site front-surface referenced least squares/range). The parameter SFQRₘₐₓ indicates the highest SFQR value for all component surfaces, for example on a silicon wafer.

A generally recognized rule of thumb states that the SFQRₘₐₓ value of a silicon wafer must be less than or equal to the possible line width on this wafer for semiconductor components which are to be fabricated thereon. If this value is exceeded, the stepper has focusing problems and therefore the corresponding component is lost. However, with regard to the optimization of costs, it is now customary for a silicon wafer not to be rejected for example on account of only one component surface exceeding the SFQRₘₐₓ value specified by the further processor. Now it is acceptable to permit a defined percentage, generally 1%, of the component areas to have higher values.

According to the prior art, it is possible to produce a silicon semiconductor wafer by means of the process sequence of sawing up a silicon single crystal, rounding the mechanically sensitive edges, carrying out an abrasive step, such as grinding or lapping, followed by polishing. EP 547 894 A1 describes a lapping process; and grinding processes are described in EP 272 531 A1 and EP 580 162 A1.

The final flatness is generally produced by the polishing process, which, if appropriate, may be preceded by an etching step for removal of flawed crystal layers and for removal of impurities. A suitable etching process is known, for example, from DE 198 33 257 C1. While conventional single-side polishing processes generally lead to reduced plane-parallelism, with newly developed double-side polishing processes it is possible to produce silicon wafers of improved flatness if certain boundary conditions are observed.

It is described in U.S. Pat. No. 4,579,760, U.S. Pat. No. 5,821,166, EP 750 967 A2 and DE 198 41 473 A1 that silicon wafers with a concave, i.e. dish-like thickness distribution, which can be produced, for example, during grinding or during etching, may be advantageous as starting material for the double-side polishing. According to the processes described in the documents cited, the result is double-side polished, convex, i.e. dome-like silicon wafers with an edge rolloff.

With regard to single-side polishing of semiconductor wafers, U.S. Pat. No. 6,080,042 recommends accurate monitoring of the starting thicknesses of the wafers, in order to prevent the polishing plate from tilting. On the other hand, in the case of polishing processes which act on both sides, monitoring of this type has not hitherto been deemed necessary, since in these processes the different thicknesses are rapidly leveled out.

DE 199 05 737 C2 describes a process for double-side polishing in which the silicon wafers are moved in stainless steel carriers between two rotating polishing plates, which are covered with a polishing cloth, in the presence of a polishing abrasive along a curved path. In this case, carriers are used whose thickness is such that the final thickness of the finished polished wafers is 2 μm to 20 μm greater than that of the carrier. Carriers are used where the range from 5 μm to 15 μm is particularly preferred for the final wafer thickness being greater than the carrier thickness. With the processes described, it is possible to produce silicon wafers with SFQRₘₐₓ values of less than or equal to 0.13 μm in economically viable yields of greater than or equal to 90%.

It is described in DE 199 38 340 C1 that a layer, for example of silicon, which is grown in single-crystal form and has the same crystal orientation, known as an epitaxial coating, to which semiconductor components can be applied, can be applied to single-crystal silicon wafers of this type. Systems of this type have certain advantages compared to silicon wafers comprising a homogeneous material, for example the prevention of charge reversal in bipolar CMOS circuits followed by short circuiting of the component (latch-up problem). Other advantages include lower defect densities (for example reduced number of COPs=crystal-originated particles) and the absence of a significant oxygen content (no risk of short circuits being caused by oxygen precipitates in regions which are relevant to the components). The deposition of an epitaxial coating with a thickness of a few μm leads, depending on the application process and the layer thickness, to an increase in the SFQRₘₐₓ value of the silicon wafer of approximately 0.01 μm to 0.05 μm. This leads to a small number of the wafers which after the double-side polishing had an SFQRₘₐₓ value of less than or equal to 0.13 μm no longer satisfying this condition after application of the coating.

Therefore, after wafers with SFQRₘₐₓ values of greater than 0.13 μm have been discarded, a quantity of epitaxially coated silicon wafers which have been produced in this way which is still economically viable is suitable for further processing to form components used for 0.13 μm technology. However, according to the prior art it is impossible to produce wafers which after, application of the coating have SFQRₘₐₓ values of less than or equal to 0.10 μm and therefore are suitable as starting material for the fabrication of components used in the 0.10 μm technology, in economically viable yields. However, wafers of this type are required by the semiconductor industry in order to reduce the line width and therefore to fabricate even more powerful electronic components, such as processors or memory elements.

### SUMMARY OF THE INVENTION

Therefore, it is an object of the present invention to provide an epitaxially coated silicon wafer by means of an inexpensive production process, which has an SFQRₘₐₓ value of less than or equal to 0.10 μm and is therefore suitable for the fabrication of electronic components with line widths of less than or equal to 0.10 μm. Furthermore, the further properties of the wafer should be at least as good as those of epitaxially coated silicon wafers produced in accordance with the prior art.

The present invention relates to a silicon wafer having a diameter of greater than or equal to 200 mm and a front surface and a back surface, the front surface and the back surface being polished and at least the front surface having an epitaxial coating with a thickness of 0.5 μm to 5 μm, which wafer has a maximum local flatness value SFQRₘₐₓ of less than or equal to 0.10 μm, based on at least 99% of all subregions of a surface grid of segments with a size of 26 mm×8 mm on the front surface of the coated silicon wafer, and a slightly convex thickness distribution and a flatness value SFQRₘₐₓ of less than or equal to 0.08 μm, defined in the same way, before application of the coating.

The present invention also relates to a process for producing silicon wafers of this type by means of a process sequence comprising sawing up a silicon single crystal, carrying out an abrasive step during which from 10 μm to 60 μm of silicon is removed from at least one surface of the silicon wafers, simultaneously polishing a front surface and a back surface of at least three silicon wafers between polishing plates which rotate in opposite directions in cutouts in an uneven number of at least three planar, rotating carriers, with a total of from 5 μm to 50 μm of silicon being removed, and applying an epitaxial coating with a thickness of 0.5 μm to 5 μm to at least the front surface of the silicon wafers, which process includes the following conditions being satisfied simultaneously:

(a) before the simultaneous polishing, the silicon wafers have a concave thickness distribution, the center thickness being 1 μm to 10 μm lower than the edge thickness, and this thickness difference differing by less than or equal to 3 μm within one polishing run;

(b) the mean thickness of the silicon wafers prior to the simultaneous polishing differs by less than or equal to 3 μm within one polishing run; and

(c) the thickness of the carriers used during the simultaneous polishing is 1 μm to 5 μm lower than the thickness of the finished polished silicon wafers.

A significant feature of the invention is that the silicon wafer, prior to the application of the epitaxial coating, has a flatness SFQRₘₐₓ of less than or equal to 0.08 μm, which compensates for a slight deterioration in this parameter as a result of the coating. A further significant feature of the invention is that such a high flatness of the double-side polished wafer can only be achieved by setting very narrow limits for the variables (a) shape distribution of the starting wafers, (b) thickness distribution of the starting wafer, and (c) thickness difference between carrier and finished polished silicon wafer. If these variables are selected optimally, the invention even makes it possible to produce epitaxially coated silicon wafers which could be suitable for the planned 0.07 μm technology generation. The discovery of the claimed narrow window for the abovementioned variables is the result of extensive tests carried out on an operational scale, the results of which were unexpectedly surprising and impossible to predict.

The starting product for the process is a cylindrically ground silicon single crystal which has been cut to length, possibly divided into pieces and has a diameter which is sufficient for the production of silicon wafers with a diameter of greater than or equal to 200 mm. If desired, the crystal may be provided with one or more orientation features to identify the crystal axes, for example a notch and/or a flat.

The end product of the process is a silicon wafer with a polished and epitaxially coated front surface and a polished back surface. This wafer satisfies the demands imposed on silicon wafers as starting material for processes for the fabrication of semiconductor components with line widths of less than or equal to 0.10 μm and which can be provided at acceptable production costs on account of high yields. The end product of the process may also be a silicon wafer with a polished and epitaxially coated front surface and a polished and epitaxially coated back surface.

In principle, the process according to the invention can be used to produce a body in wafer form which consists of a material which can be processed using the abrasive, polishing and coating processes which are used. Silicon and silicon-containing materials are most suitable. Silicon in single crystal form with a (100) crystal orientation is particularly preferred. In this case, the silicon contains a certain quantity of dopant. A distinction is made between dopants from the 3^{rd} main group of the period system of the elements, for example boron, which lead to material of the p-type, and elements belonging to the 5^{th} main group, for example phosphorus, arsenic or antimony, which lead to material of the n-type.

The process is particularly suitable for the production of silicon wafers with diameters of greater than or equal to 200 mm. The market requires standard diameter sizes of 200 mm, 300 mm and 450 mm and thicknesses in the range from 500 μm to 1000 μm. In the first step, the silicon single crystal is sawn into silicon wafers using methods which are known to the person skilled in the art, for example by means of an internal-diameter or wire sawing process. Then, however, it is sensible and therefore preferred for the sharply delimited and therefore mechanically highly sensitive wafer edge to be rounded with the aid of a suitably profiled grinding wheel. However, this edge rounding may also take place elsewhere in the further process sequence, but it is advisable that it should be carried out before the polishing.

At this point, the invention provides for an abrasive step to be carried out, in which silicon, preferably a total of 10 μm to 60 μm of silicon, is removed from at least one surface of the silicon wafers. This abrasive step, which is generally carried out as a grinding or lapping step, is used firstly for partial removal of the crystal layers which have been damaged during sawing. During lapping, the silicon wafers are moved with the aid of carriers between a rotating upper working wheel and an oppositely rotating lower working wheel. This wheel can be made from cast iron with the addition of a suspension which contains abrasive particles, for example of silicon carbide, with the aid of carriers. The process is therefore similar to the double-side polishing of silicon wafers. By optimizing the lapping parameters, such as pressure and rotational speed, the person skilled in the art is able to produce wafers which have a concave thickness distribution.

An alternative possibility for carrying out the abrasive step is grinding, which can be carried out as grinding of only one surface or as sequential grinding of both surfaces or as simultaneous grinding of both surfaces of the silicon wafer. In the context of the process according to the invention, the method of sequential rotary surface grinding is particularly preferred. In this method, both the wafer holder, for example a vacuum chuck, with the silicon wafer fixed on it and the grinding wheel which is advanced in the axial direction, for example a plate grinding wheel, rotate. In this case, it is preferred to use diamond-containing grinding wheels, particularly preferably resin-bonded grinding wheels with diamonds with a grain size of 600 mesh (20 μm to 30 μm) to 2000 mesh (3 μm to 5 μm).

In accordance with a procedure which is disclosed in EP 580 162 A1, the rotary surface grinding method allows deliberate shaping of the machined silicon wafer by adjustment of the angle between wafer holder and rotating grinding wheel. If the wafer holder and grinding wheel are arranged parallel to one another, the result is a virtually plane-parallel form of the machined silicon wafer. If the axis of rotation of the grinding wheel is inclined with respect to the axis of rotation of the wafer holder, the result is a silicon wafer with a rotationally symmetrically curved surface which may be of concave, convex or conical design. The curvature of the wafer surface is dependent on the angle of inclination which the axes of rotation of wafer holder and grinding wheel form during the rotary surface grinding and can therefore be set in a defined way.

To remove the damage to wafer surface and edge, which has been produced in the previous mechanical processes, including any impurities which may be present, an etching step, which may be carried out as a wet-chemical or a plasma etching step, may be carried out at this point in the process sequence. Under certain preconditions, for example the use of a grinding process with a very fine diamond grain size, such as mesh 2000, it is possible to dispense with the etching step, which is not of relevance to the invention. A process sequence which dispenses with the etching step is preferred in these cases.

However, if it is appropriate for an etching step to be carried out, wet-chemical etching using an acidic etching mixture and a removal of 3 μm to 30 μm of silicon is preferred. If a silicon wafer with a concave thickness distribution has already been produced in the abrasive step of the process according to the invention, the etching step may be carried out in accordance with the prior art, for example as described in DE 199 33 257 C1. This uses the rotary principle with gas being fed in while maintaining the predetermined wafer geometry. However, within the context of the invention it is also possible for the concave thickness distribution of the silicon wafers to be produced for the first time in the etching step or to be enhanced in the etching step. There are various possibilities in this respect, defined by the choice of process parameters; their effect on the wafer geometry is in this case generally determined by processing and measuring test wafers. This leads to an optimized set of parameters which results in etched wafers with a defined concave thickness distribution. In the case of the preferred acid etching process, it is possible to produce concave wafers for example by reducing the dissipation of heat or reducing the quantity of gas which is fed in.

Within the context of the invention, after the abrasive step and optionally the etching step have been carried out, at this point a silicon wafer with a concave thickness distribution is present, the center thickness preferably being 1 μm to 10 μm, particularly preferably 3 μm to 6 μm, lower than the edge thickness. With regard to the core of the invention, it is in principle irrelevant whether the concave form has been produced by the abrasive step or—if carried out—by the etching step or by both the abrasive step and the etching step. However, with a view to a simple process sequence, it is particularly preferred for the concave form to be produced in the abrasive step and for any etching step which is carried out to be optimized with regard to maintaining the shape.

At this point in the process sequence, it is preferable to form groups of silicon wafers which are simultaneously subjected to double-side polishing. Depending on the size and occupancy of the polishing machine, these groups may, for example, be 15 or 30 wafers with a diameter of 200 mm or 5 or 15 wafers with a diameter of 300 mm or 3 or 5 wafers with a diameter of 450 mm. It is possible for the wafers to be grouped without measurements if the thickness and shape are very highly constant. However, to ensure robust process management in everyday operation, a sorting station is generally required. This sorting station is equipped with a measuring unit for determining wafer thickness and shape and a sorting unit having at least one entry station and a plurality of exit stations for cartridges for holding the sorted silicon wafers. The wafers are then brought together for a polishing run in such a manner that (a) the difference between center thickness and edge thickness of the wafers. These wafers preferably have a concavity of 1 μm to 10 μm, which differs by preferably less than or equal to 3 μm, particularly preferably by less than or equal to 2 μm, for example 4 μm±1 μm. Also (b) the mean thickness of the silicon wafers differs within a thickness range of preferably less than or equal to 3 μm and particularly preferably less than or equal to 2 μm, for example within ±1 μm. If the process steps which have been described hitherto are carried out correctly, this sorting is possible virtually without losses of wafers as a result of extreme shape and thickness data.

To carry out the double-side polishing step, it is possible to use a commercially available installation of suitable size. The polishing machine substantially comprises a lower polishing plate, which can rotate freely in the horizontal plane, and an upper polishing plate, which can rotate freely in the horizontal plane, which plates are both covered with polishing cloth. The machine allows double-side abrasive polishing of silicon wafers with a polishing abrasive of suitable chemical composition being supplied continuously. In this case, at least three silicon wafers are held on a geometric path, which is determined by machine and process parameters, during the polishing by an odd number of at least three carriers which have adequately dimensioned cutouts for receiving the silicon wafers. The simultaneous use of three or five carriers, which are each occupied by at least one silicon wafer, is preferred. Using a pin gearing, by way of example, the carriers are connected to the polishing machine via rotating pin gears and as a result are set in rotary motion between the two polishing plates.

Within the context of the invention, the use of planar carriers is obligatory. The carriers should preferably also be free from distortion and substantially resistant to abrasion. Carriers of this type preferably consist of steel, particularly preferably of stainless chromium steel. To prevent the edge of the wafers from being damaged by the inner edge of the cutout in the carrier during the polishing, it is sensible and therefore preferred for the inner side of the cutouts to be lined with a plastic coating of the same thickness as the carrier, as proposed in EP 208 315 B1. The double-side polishing with removal of a total of preferably 5 μm to 50 μm of silicon and particularly preferably of 20 μm to 40 μm of silicon is carried out in such a way, by selecting the carrier set used, that the final thickness of the polished silicon wafers is 1 μm to 5 μm greater than the thickness of the carriers. This is a very narrow window for the thickness difference, which closely interacts with the shape and thickness distribution prior to the polishing and does not coincide with the particularly preferred range described in DE 199 250 737 C2 (5 μm to 15 μm).

Within the context of the invention, for the double-side polishing the following possibilities are proposed for the procedure with regard to the different thickness groups which are present after the sorting:

(1) Given a relatively narrow distribution of the main thicknesses and therefore only a small number of thickness classes, for example when the abrasive step is carried out as a grinding step, a carrier thickness which is suitable for all sorted classes is selected. A variation in the amount of material which is removed around the target removal is accepted, in which case a minimum amount of material removed, which is to be defined, must be ensured. The scatter in the amount of material removed can be restricted still further by utilizing the inventive range of 1 μm to 5 μm for the silicon wafer/carrier thickness difference.

(2) If there is a relatively wide distribution of the mean thicknesses and therefore a greater number of thickness classes during sorting, for example if the abrasive step is carried out as a lapping process, different carrier sets of suitable thicknesses are selected. This selection is for each thickness class or for subgroups of thickness classes which are close together.

With regard to the thickness ratios, the double-side polishing is preferably carried out in the manner which is known to the person skilled in the art. Polishing cloths are commercially available with a wide range of properties. Polishing is preferably carried out using a commercially available polyurethane polishing cloth with a hardness of 50 to 100 (Shore A). Polyurethane cloths with incorporated polyester fibers and a hardness range of 60 to 90 (Shore A) are particularly preferred. It is recommended that a polishing abrasive with a pH of preferably 10 to 12.5, particularly preferably 11 to 12, preferably comprising 1% by weight to 10% by weight, particularly preferably 1% by weight to 5% by weight, of SiO₂ in water, be supplied continuously. The percent by weight of SiO₂ is based upon the total weight of the polishing abrasive. The silicon removal rate is preferably 0.2 μm/min to 2 μm/min, particularly preferably 0.5 μm/min to 1.5 μm/min.

After the polishing has ended, any adhering polishing abrasive is cleaned off the silicon wafers, and the wafers are dried and can then be measured with regard to their local geometry SFQR on a commercially available geometry-measuring unit. This unit operates, for example, capactively or optically. Using the standard grid divisions, for example 112 rectangular component areas of 25 mm×25 mm edge length or 328 component areas of 26 mm×8 mm, the result at this point, taking account of 99% of the individual areas (i.e. for 25 mm×25 mm one value and for 26 mm×8 mm three values may be excluded), is typical SFQRₘₐₓ values of 0.04 μm to 0.07 μm. Virtually all the wafers have SFQRₘₐₓ values of less than or equal to 0.08 μm. The typical wafer shape after the double-side polishing according to the invention is, in the same way as before the polishing, concave without edge rolloff, but with only a very slight difference in thickness between the edge and the center of preferably 0.2 μm to 2 μm, particularly preferably 0.3 μm to 1 μm, which corresponds to the total thickness variation of the silicon wafer.

Depending on its further destination, it may be necessary for at least the wafer front surface, for example for further smoothing or to reduce the number of defects, to be subjected to surface polishing in accordance with the prior art. For example a soft polishing cloth may be used with the aid of an alkaline polishing abrasive based on SiO₂. To maintain the very low SFQRₘₐₓ values which are present at this point, the amount of silicon removed should be relatively low, for example only 0.1 μm to 1 μm. Of course, the silicon wafers may be fed for use in the fabrication of semiconductor components with slightly lesser requirements even in the state in which they leave the double-side polishing and optionally the surface polishing.

The silicon wafers which have been prepared in this way are then provided with an epitaxial coating at least on the front surface, using standard processes. Silicon or silicon/germanium is a preferred coating material. Silicon is particularly preferred, in which case silicon wafer and epitaxial coating are preferably either both of the p-type or both of the n-type. The epitaxial coating, for example of silicon, often differs from the silicon wafer in terms of its electrical properties, on account of its dopant content, a fact which is utilized in the design of the integrated semiconductor components. However, this is not absolutely imperative.

An epitaxial silicon layer is preferably applied using the CVD (chemical vapor deposition) process as a result of silanes, for example silane (SiH₄), dichlorosilane (SiH₂Cl₂) or trichlorosilane (SiHCl₃) being fed to the wafer surface, where they decompose at temperatures of from 900° C. to 1250° C. to form elemental silicon and volatile byproducts and form an epitaxial silicon layer. Thus a single-crystal silicon layer is grown in a crystallographically oriented fashion on the silicon wafer. It is possible to use pure-isotope silicon compounds, and this may give advantages with regard to the defect density. Epitaxial growth of silicon layers with a thickness of from 0.5 μm to 5 μm is preferred.

After the epitaxial coating of at least the front surface has been carried out, the result is a silicon wafer according to the invention which has a hydrophobic surface and can be fed in this form for further processing for fabrication of integrated components. However, it is preferable for the wafer surface to be rendered hydrophilic in order to protect it against contamination, i.e. for the surface to be coated with a thin film of oxide, for example an oxide film with a thickness of approximately 1 nm, which is known to the person skilled in the art as “native oxide”. In principle, this can be carried out in two different ways: firstly, the surface of the epitaxially coated silicon wafer can be treated with a gas which has an oxidizing action, for example ozone, which can be carried out in the epitaxy chamber itself or in a separate installation. Secondly, the wafer can be rendered hydrophilic in a bath installation, for example using an aqueous solution which contains hydrogen peroxide.

After the process sequence according to the invention has been carried out, silicon wafers which have been epitaxially coated at least on a front surface and which have a polished back surface are the result. These wafers can be fed for characterization of their properties before being processed further for the fabrication of semiconductor components. This characterization primarily involves measuring the local flatness as after the double-side polishing, resulting in typical SFQRₘₐₓ values of 0.05 μm to 0.08 μm, with virtually all the wafers having SFQRₘₐₓ values of less than or equal to 0.10 μm (26 mm×8 mm; 99%).

If necessary, a heat treatment of the silicon wafer may be introduced at any desired point in the process sequence, for example in order to anneal damage to crystal layers close to the surface. Furthermore, laser marking for wafer identification and/or an edge polishing step may be inserted at suitable locations, for example after the abrasive step in the case of laser marking and before, during or after the double-side polishing in the case of edge polishing. A range of further process steps which are required for certain products can be carried out. For example the application of back-surface coatings comprising polysilicon, silicon dioxide or silicon nitride, can likewise usefully be incorporated in the process sequence using the process which is known to the person skilled in the art. In addition to the production of wafers comprising a homogeneous material, the invention may also, of course, be used for the production of semiconductor substrates which are of multilayer structure, such as SOI (silicon-on-insulator) wafers, although in this case cost benefits and high local flatness are lost. Furthermore, it may be expedient for the silicon wafer to be subjected to a batch or individual-wafer cleaning operation using aqueous solutions or gases, such as HCl, before or after individual process steps.

With regard to the further parameters which are customarily used for wafer characterization and are well known to the person skilled in the art, a silicon wafer which has been produced in accordance with the invention does not have any drawbacks compared to a silicon wafer which has been produced in accordance with the prior art. An epitaxially coated silicon wafer which has been produced in accordance with the invention, on account of its high local flatness which the invention has made possible, in combination with the low-defect surface produced by the coating principle, satisfies the demands imposed on silicon wafers for the fabrication of semiconductor components with line widths of less than or equal to 0.10 μm in high yields. Surprisingly and unexpectedly, only a relatively narrow window for the combination of parameters of wafer shape, wafer shape distribution and wafer thickness distribution prior to the double-side polishing in combination with the low thickness difference between polished silicon wafers and carriers during the double-side polishing leads to this result.

### BRIEF DESCRIPTION OF THE DRAWINGS

Figures which illustrate the invention belong to the Comparative Example and Example described below. These figures are of only exemplary nature, in particular with regard to the structure of an installation for the double-side polishing of silicon wafers and its occupancy and with regard to the arrangement of the surface grid for the flatness determination, in which

FIG. 1 diagrammatically depicts the arrangement of silicon wafers 1 and carriers 2 in an installation for the double-side polishing of silicon wafers with a diameter of 300 mm, as used for the Comparative Example and the Example;

FIG. 2 shows the distribution of the local flatness values SFQR for subregions which are arranged so as to cover the surface (328 area elements) with a size of 26 mm×8 mm on a silicon wafer with a diameter of 300 mm which has been produced in accordance with the Comparative Example, polished on both sides and epitaxially coated;

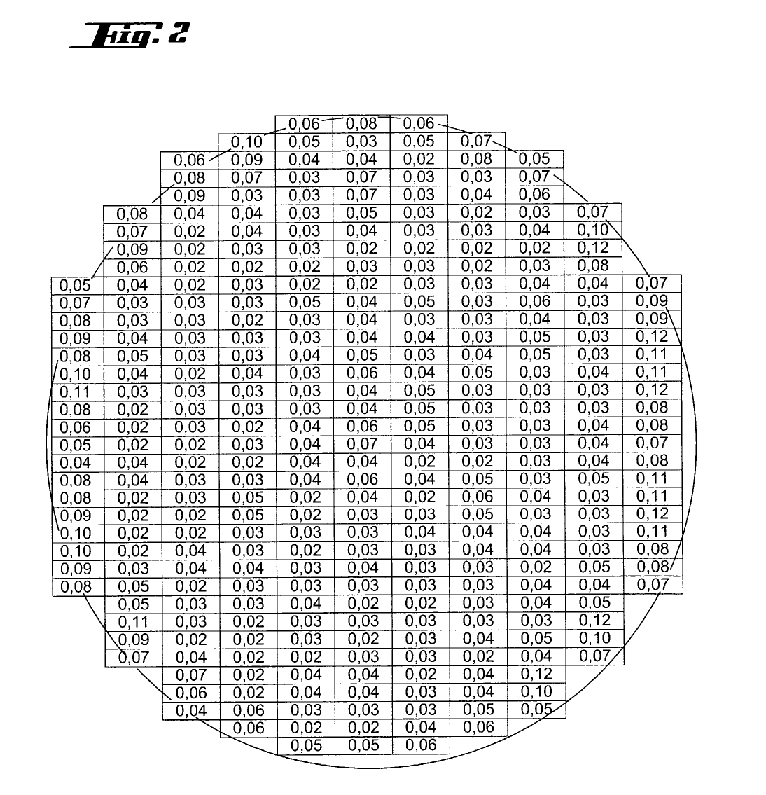

FIG. 3 shows the distribution of the local flatness values SFQR for subregions which are arranged so as to cover the surface (328 area elements) with a size of 26 mm×8 mm for a silicon wafer with a diameter of 300 mm which has been produced in accordance with the Example, polished on both sides and epitaxially coated; and

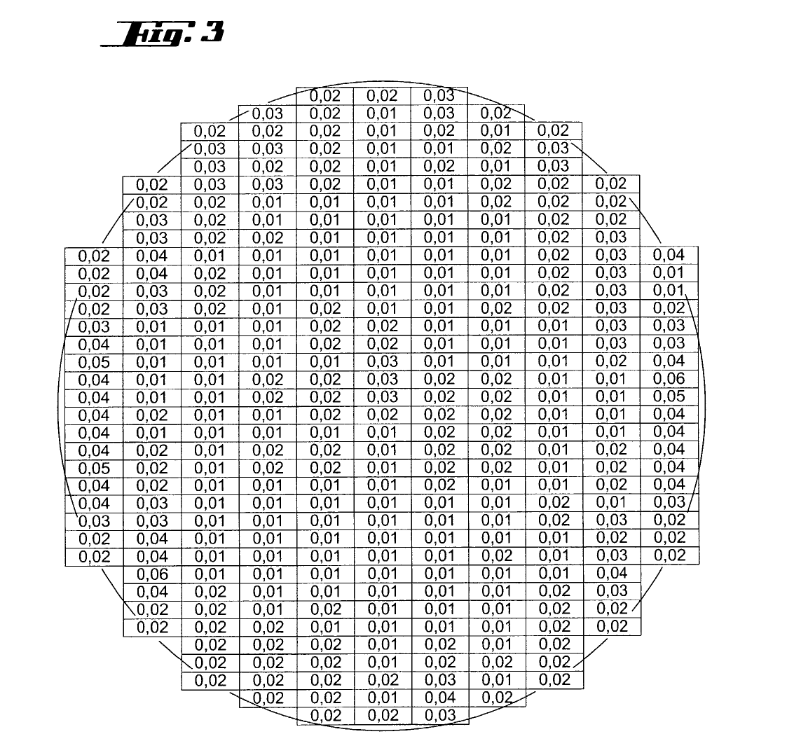

FIG. 4 shows as a “box & whisker plot” the distribution of the SFQRₘₐₓ values for the silicon wafers with a diameter of 300 mm which have been produced using the Comparative Example (V) and the Example (B) immediately after the doubleside polishing and after application of the epitaxial coating. The boxes comprise 80% of the data, with an additional line indicating the mean; the vertical lines (whiskers) mark the area in which 99% of the data lie.

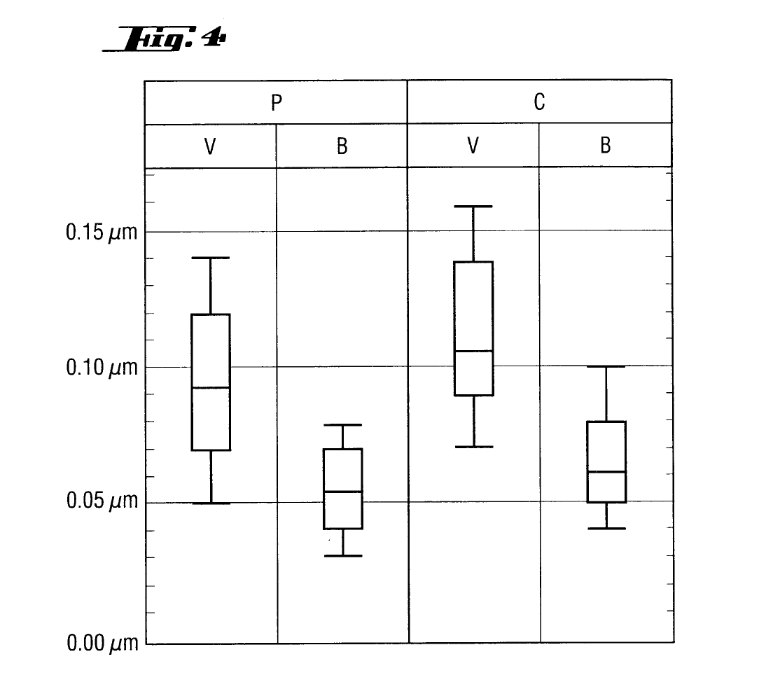

### DETAILED DECRIPTION OF THE PREFERRED EMBODIMENTS

The Comparative Example and the Example relate to the production of silicon wafers with a diameter of 300 mm, a thickness of 778 μm, a surface-polished front surface with an epitaxially deposited silicon layer and a polished back surface. The crystals required for this purpose were pulled in accordance with the prior art, cut to length, cylindrically ground, divided into portions, sawn into wafers with a thickness of 905 μm on a commercially available wire saw and subjected to edge-rounding. The Comparative Example and the Example were carried out using a statistically relevant quantity of wafers, in each case comprising approximately 1500 wafers.

### Comparative Example

The edge-rounded wafers were ground on a rotary grinding machine with a resin-bonded grinding wheel comprising diamonds with a grain size of 600 mesh, with in each case 40 μm of silicon being abraded sequentially from a front surface and a back surface of the wafers, with a set of machine parameters which did not lead to preferential shaping being selected. This was followed by an etching step in a mixture of concentrated nitric acid and concentrated hydrofluoric acid at 20° C.; there was a laminar flow of 100 l/h of nitrogen gas through the etching mixture, and in each case 10 μm of silicon were removed from each side of the wafer simultaneously with rotation.

The mean thickness of the wafers was then 805 μm; as well as wafers which were virtually planar, there were specimens with a slightly concave or convex thickness distribution. During the sequence of arrival in the polishing region as part of operational production, the wafers were combined into groups of 15 for in each case one run in the double-side polishing. Within these groups of 15, the mean thicknesses of the silicon wafers differed within a range from 801 μm to 809 μm.

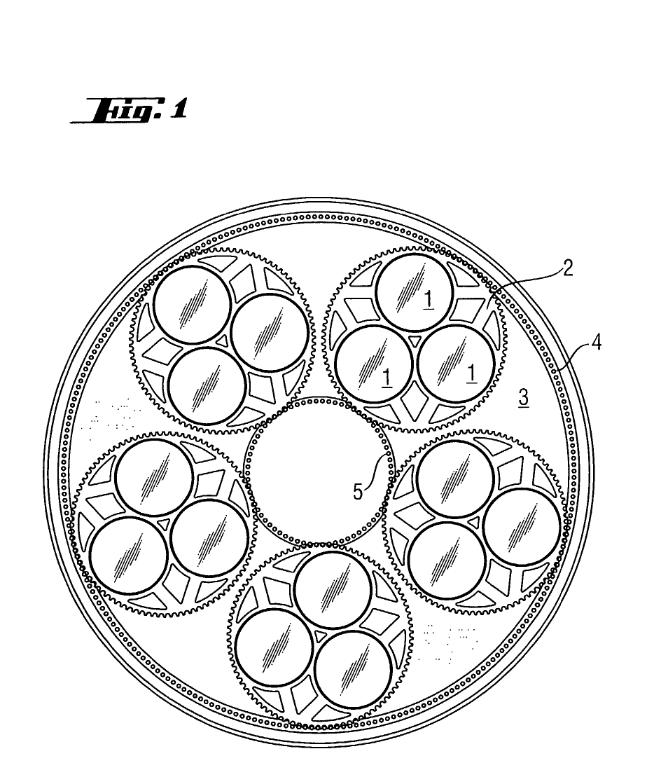

This was followed by a double-side polishing step using a polyester fiber-reinforced polyurethane polishing cloth with a hardness of 64 (Shore A), between a rotating lower polishing plate and an oppositely rotating upper polishing plate, using a polishing abrasive with a SiO₂ solids content of 3% by weight and a pH of 11.5 with a material removal rate of 0.8 μm/min, with 15 silicon wafers being polished simultaneously. The arrangement of the 15 silicon wafers 1 in the five planar carriers 2 made from hardened chromium steel, the openings of which, for receiving the silicon wafers, had injection-molded plastic linings comprising PVDF of the same thickness as the carrier, can be seen in FIG. 1. In this figure, 3 denotes the lower polishing plate with the polishing installation open, 4 denotes the outer pinned wheel for driving the carriers and 5 denotes the inner pinned wheel for driving the carriers. The thickness of the carriers used (767 μm) was such that, after removal of on average 30 μm of silicon, the finished polished silicon wafers (775 μm thickness) was 8 μm thicker than the carriers. Accordingly, in this process the amount of silicon removed within one polishing run could vary by up to 8 μm from wafer to wafer.

The mean SFQRₘₐₓ value (99% for a grid size of 26 mm×8 mm) of the double-side polished silicon wafers produced in this way was 0.092 μm with a distribution of 0.05 μm to 0.14 μm (99% of the wafers), assessed in accordance with a measurement which operates using the capacitive principle and with an edge exclusion of 3 mm.

This was followed by surface polishing of the wafer front surfaces using a soft polishing cloth and an alkaline polishing abrasive based on SiO₂, during which step 0.5 μm of silicon was removed, followed by bath cleaning and drying. The silicon wafers which had been prepared in this way were provided with an epitaxially grown silicon layer on the front surface in a commercially available 300-mm epitaxy reactor, during which step the silicon component used was SiHCl₃ and the resistance was set by doping using diborane, B₂H₆. At a reactor chamber temperature of 1090° C. and a deposition rate of 3 μm/min, a 3.5 μm thick layer was deposited (final thickness of the silicon wafers 778 μm).

After they had been cleaned, rendered hydrophilic and dried, the wafers were measured again as described above. The mean SFQRₘₐₓ value (99% for a grid size of 26 mm×8 mm) of the double-side polished silicon wafers, which had been produced in this way and epitaxially coated on the front surface, was 0.105 μm with a distribution from 0.07 μm to 0.16 μm (99% of the wafers). Just under 90% of these wafers were suitable for use in the fabrication of components using 0.13 μm technology. However, only approximately 30% had an SFQRₘₐₓ value of less than or equal to 0.10 μm, and consequently it was not feasible for the entire quantity of the silicon wafers produced in this way to be employed for the fabrication of components belonging to the 0.10 μm technology, for example after the residual quantity has been sorted out and discarded, for cost reasons.

### EXAMPLE

The procedure was as in the Comparative Example, with the following differences:

(1) The grinding process was carried out in such a way that a concave thickness distribution was produced by inclining the axis of rotation of the grinding wheel with respect to that of the wafer holder.

(2) Before the double-side polishing, the silicon wafers were divided into groups of 15 wafers which were to be polished simultaneously and in which the thickness difference between wafer edge and wafer center within each group was 4 μm±1 μm.

(3) During the sorting into groups, account was also taken of the fact that the distribution (in accordance with the Comparative Example) of the mean thicknesses of the silicon wafers within each group was ±1 μm. Overall, therefore, four thickness groups were produced ([802±1] μm; [804±1] μm; [806±1] μm; [808±1] μm).

(4) For the double-side polishing, carriers with a thickness of 773 μm were used, and all the silicon wafers were polished to a thickness of 775 μm, so that after polishing they were 2 μm thicker than the carriers.

The amount of silicon removed within one polishing run in this process varied by only at most 2 μm from wafer to wafer. The mean SFQRₘₐₓ value (99% for a grid size of 26 mm×8 mm) of the double-side polished silicon wafers produced in this way was 0.054 μm with a distribution from 0.03 μm to 0.08 μm (99% of the wafers). After surface polishing and application of the epitaxial coating, the mean SFQRₘₐₓ value was 0.062 μm with a distribution from 0.04 μm to 0.10 μm (99% of the wafers). With regard to all the other parameters which were checked, such as roughness, defect density on the front surface and absence of surface scratches, the wafers produced using the Example were comparable to the wafers produced using the Comparative Example. Furthermore, the entire quantity of the silicon wafers produced in accordance with the Example were able to be used without problems for the fabrication of components belonging to the 0.10 μm technology, without the production costs being any higher than those of the wafers produced in accordance with the Comparative Example.

Accordingly, while only several embodiments of the present invention have been shown and described, it is to be understood that many changes and modifications may be made thereunto without departing from the spirit and scope of the invention as defined in the appended claims.

What is claimed is:

1. A silicon wafer having a diameter of at least 200 mm and a front surface and a back surface, comprising
said front surface and said back surface being polished and at least said front surface having an epitaxial coating with a thickness of 0.5 μm to 5 μm;
said wafer having a maximum local flatness value SFQRₘₐₓ of at most 0.10 μm, based on at least 99% of all subregions of a surface grid of segments with a size of 26 mm×8 mm on the front surface of the coated silicon wafer; and
said wafer having a slightly convex thickness distribution and a flatness value SFQRₘₐₓ of less than or equal to 0.08 μm, defined in the same way, before application of the epitaxial coating.

2. A process for producing silicon wafers as claimed in claim 1 by means of a process sequence comprising
sawing a silicon single crystal into silicon wafers;
carrying out an abrasive step during which from 10 μm to 60 μm of silicon is removed from at least one surface of the silicon wafers;
simultaneously polishing a front surface and a back surface of at least three silicon wafers between polishing plates which rotate in opposite directions in cutouts in an uneven number of at least three planar, rotating carriers, with a total of from 5 μm to 50 μm of silicon being removed; and
applying an epitaxial coating with a thickness of 0.5 μm to 5 μm to at least the front surface of the silicon wafers, which process includes the following conditions being satisfied simultaneously:
(a) before the simultaneous polishing, the silicon wafers have a concave thickness distribution, with a center thickness being 1 μm to 10 μm lower than an edge thickness, and a thickness difference differing by at most 3 μm within one polishing run;
(b) a mean thickness of the silicon wafers prior to the simultaneous polishing differs by at most 3 μm within one polishing run; and
(c) a thickness of carriers used during the simultaneous polishing is 1 μm to 5 μm lower than the thickness of finished polished silicon wafers.

3. The process as claimed in claim 2, comprising
rounding edges of the silicon wafers in a manner selected from the group consisting of before the abrasive step, and after the abrasive step.

4. The process as claimed in claim 2,
wherein the abrasive step is carried out as a grinding step.

5. The process as claimed in claim 2,
wherein the abrasive step is carried out as a lapping step.

6. The process as claimed in claim 2,
wherein a wet-chemical etching step, which removes from 3 μm to 30 μm of silicon, is carried out between the abrasive step and the simultaneous polishing.

7. The process as claimed in claim 2,
wherein during the simultaneous polishing the polishing plates are covered with a polishing cloth, and during the polishing of the silicon wafer an alkaline polishing abrasive with an SiO₂ solids content of 1% by weight to 10% by weight and a pH of 10 to 12.5 is supplied continuously; and
the percent by weight of SiO₂ is based upon the total weight of the polishing abrasive.

8. The process as claimed in one of claim 2,
wherein polishing of an edge of the silicon wafers takes place in a manner selected from the group consisting of before the simultaneous polishing of the front surface and the back surface, during the simultaneous polishing of the front surface and the back surface, and after the simultaneous polishing of the front surface and the back surface.

9. The process as claimed in claim 2
wherein after the simultaneous polishing of the front surface and the back surface, carrying out a further surface polishing step of at least the front surface;
in said step further smoothing of the surface is achieved using a soft polishing cloth, with from 0.1 μm to 1 μm of further material being removed.

10. The process as claimed in claim 2,
wherein the epitaxial coating comprises silicon.

11. The process as claimed in claim 2, comprising
cleaning the surface of the silicon wafers in a manner selected from the group consisting of by wet chemical means and by means of attack of gases before the epitaxial coating is applied.

12. The process as claimed in claim 2, comprising
depositing the epitaxial coating at a temperature of from 900° C. to 1250° C.

13. The process as claimed in claim 2,
wherein the epitaxial coating is rendered hydrophilic using an oxidizing gas.

14. The process as claimed in claim 2,
wherein the epitaxial coating is rendered hydrophilic by wet-chemical means.

15. The process as claimed in one of claim 2,
wherein center thickness of the silicon wafers before the simultaneous polishing is from 3 μm to 6 μm lower than edge thickness.

16. In a method for fabricating of integrated semiconductor components, the improvement which comprises
utilizing the silicon wafer of claim 1 for said fabricating.

17. In a method for fabricating of integrated semiconductor components, wherein a silicon wafer has a flatness value SFQRₘₐₓ of at most 0.08 μm and, with an exception of an application of an epitaxial coating at least to a front surface, the improvement which comprises
utilizing the silicon wafer of claim 1 for said fabricating.
